(19) United States
(12) Patent Application Publication
(10) Pub. No.: US 2025/0157885 A1
(43) Pub. Date: May 15, 2025

(54) MEMORY MODULE WITH EXTENDED CONDUCTIVE PLANE FOR HEAT DISSIPATION

(71) Applicant: Micron Technology, Inc., Boise, ID (US)

(72) Inventors: Kaleb A. WILSON, Caldwell, ID (US); Amy R. GRIFFIN, Boise, ID (US); Mark A. TVERDY, Boise, ID (US); Bradley Russell BITZ, Meridian, ID (US)

(21) Appl. No.: 18/949,564

(22) Filed: Nov. 15, 2024

Related U.S. Application Data
(60) Provisional application No. 63/599,435, filed on Nov. 15, 2023.

(51) Int. Cl. H01L 23/473; H01L 23/31; H01L 23/498; H01L 25/065

(52) U.S. Cl. CPC H01L 23/473; H01L 23/3121; H01L 23/49811; H01L 25/0652

(57) ABSTRACT

Implementations described herein relate to various semiconductor device assemblies. In some implementations, a semiconductor device assembly includes a multi-layer substrate populated with one or more integrated circuit devices that includes one or more core layers interspersed with one or more vertically-arranged conductive layers. A conductive layer of the vertically-arranged conductive layers includes a linear array of planar fins that extends into a cavity region along an edge of the multi-layer substrate. The linear array of planar fins is configured to receive, through the conductive layer, heat that is generated by the one or more integrated circuit devices, and transfer the heat for dissipation to an environment surrounding the semiconductor device assembly.

### CROSS-REFERENCE TO RELATED APPLICATION

This Patent Application claims priority to U.S. Provisional Patent Application No. 63/599,435, filed on Nov. 15, 2023, entitled “MEMORY MODULE WITH EXTENDED CONDUCTIVE PLANE FOR HEAT DISSIPATION,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a memory module with an extended conductive plane for heat dissipation.

### BACKGROUND

An electronic system assembly, such as a memory module, may include multiple semiconductor die packages electrically coupled to a multi-layer substrate, such as a printed circuit board (PCB). The PCB may include a layer stack having dielectric layers interspersed with conductive layers. The PCB may include electrical interconnects and conductive paths through the layer stack that are used for interconnecting system components, including the multiple semiconductor die packages and other components that may be used to enable functionality of the memory module in a host computing system.

### BRIEF DESCRIPTION OF THE DRAWINGS

FIGS. 1A-1D are diagrams of an example implementation of a memory module described herein.

FIGS. 2A-2D are diagrams of an example implementation of a memory module described herein.

FIG. 3 is a flowchart of an example method associated with forming a multi-layer substrate described herein.

FIG. 4 is a flow chart of an example method associated with forming a memory module described herein.

FIGS. 5A-5F describe an example series of manufacturing operations that may be performed to form a multi-layer substrate with an extended conductive plane as described herein.

### DETAILED DESCRIPTION

A memory module may include multiple memory devices on a substrate that are configured to stored data in memory cells. In some implementations, the memory module includes volatile memory that requires power to maintain stored data and that loses stored data after the memory module is powered off, such as one or more latches and/or random-access memory (RAM), such as dynamic RAM (DRAM) and/or static RAM (SRAM). The memory module may be a single inline memory module (SIMM) with electrical contacts on a single surface of the substrate or a dual inline memory module (DIMM) with electrical contacts on opposing surfaces of the substrate.

Alternatively, the memory module may include a hard drive, a solid-state drive (SSD), a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

In a case where the memory module includes DRAM devices, environmental factors such as temperature and/or voltage may influence a rate of charge leakage from storage cells of the DRAM devices which, in turn, can adversely affect refresh performance of the DRAM devices (e.g., increase a frequency at which the storage cells are refreshed with charges corresponding to data stored within the storage cells). Increasing memory densities, increased layer counts that may be included in the substrate of the memory module, and the inclusion of additional devices on the memory module (power management integrated circuit (PMIC) devices, inductor devices, and/or regulator devices, among other examples) may exacerbate the adverse refresh performance further.

In some cases, the memory module includes a heat transfer device (e.g., a heat spreader) that is thermally coupled with surfaces of semiconductor die packages that encapsulate the DRAM devices. In such cases, a thermal control network for transferring heat from the DRAM devices to an environment surrounding the memory module may include a conductive path through a casing (e.g., a mold compound) of the semiconductor die packages. A thermal conductivity of the casing, in combination with a surface area and/or a location of the heat transfer device, may render the thermal control network insufficient for maintaining a junction temperature of the DRAM devices at or below a threshold that maintains the refresh performance of the DRAM devices.

In some implementations described herein, a memory module includes a thermal control network that uses a conductive layer included in a substrate of the memory module. The conductive layer, which may correspond to a ground plane layer, may be formed from a metal material having a high thermal conductivity relative to other materials. As part of the thermal control network, a linear array of planar fins that is part of the conductive layer extends into a cavity region proximate to an edge of the substrate. The conductive layer may be connected to DRAM devices of the memory module using interconnects that are routed through layers of the substrate and/or connection structures that connect semiconductor die packages including the DRAM devices with the substrate. By transferring heat through the connection structures, through the interconnects, and through the conductive layer to the linear array of planar fins for dissipation, the thermal control network of the memory module has an improved heat transfer efficiency relative to another thermal control network that transfers heat from the DRAM devices through a casing and a heat spreader above the DRAM devices.

In this way, the thermal control network maintains a junction temperature of the DRAM devices at or below a threshold temperature that adversely affects a refresh performance of the DRAM devices. By maintaining the refresh performance of the DRAM devices, the memory module realizes improved performance benefits that may include improved data retention, improved stability, lower power consumption, and/or lower heat generation, among other examples.

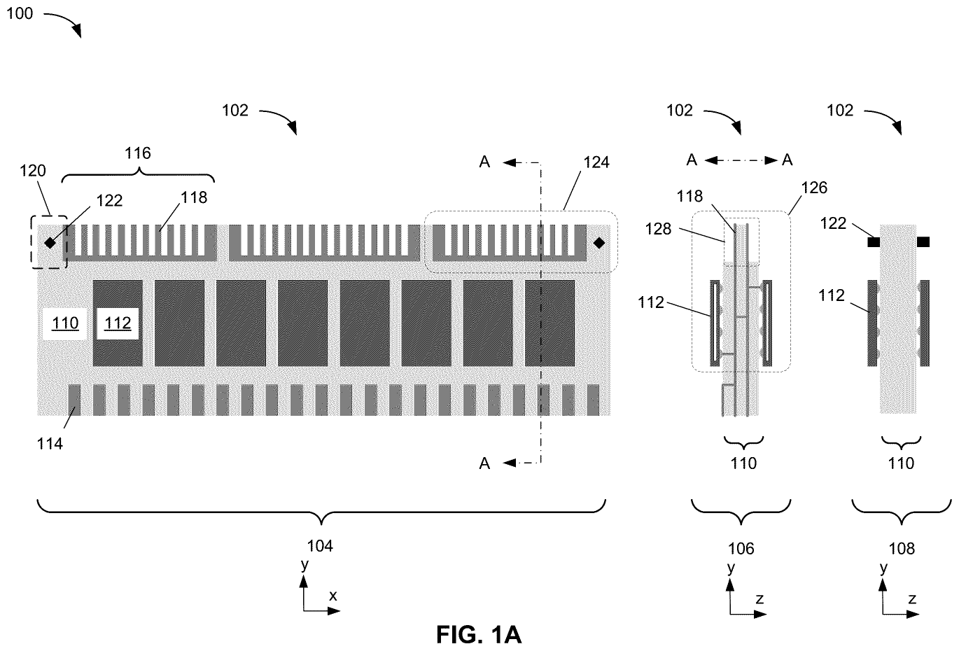

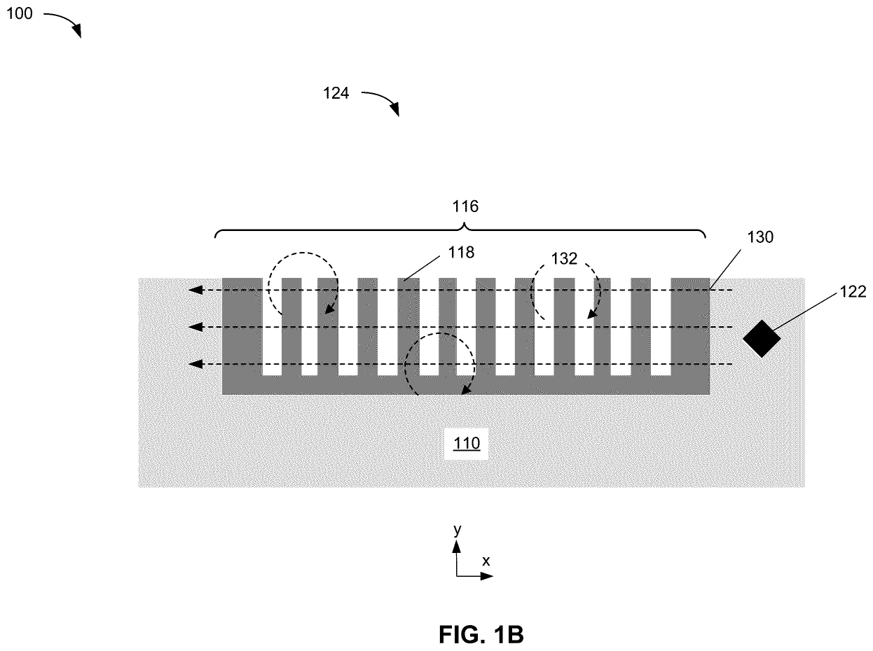

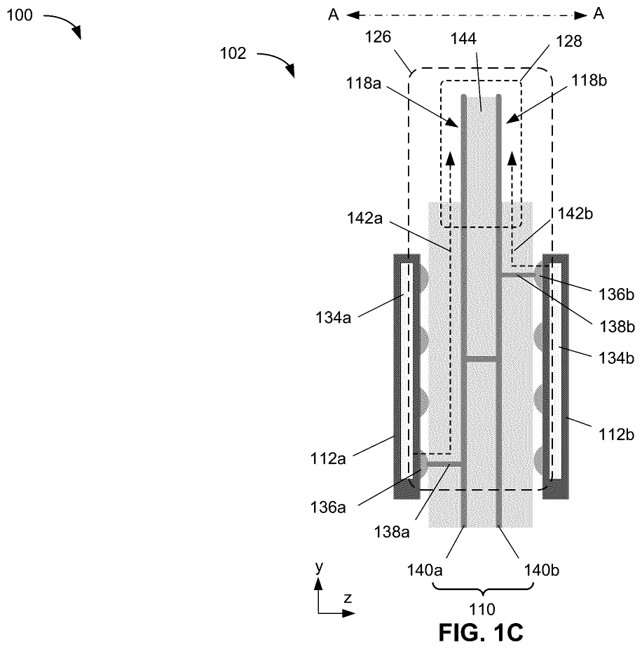

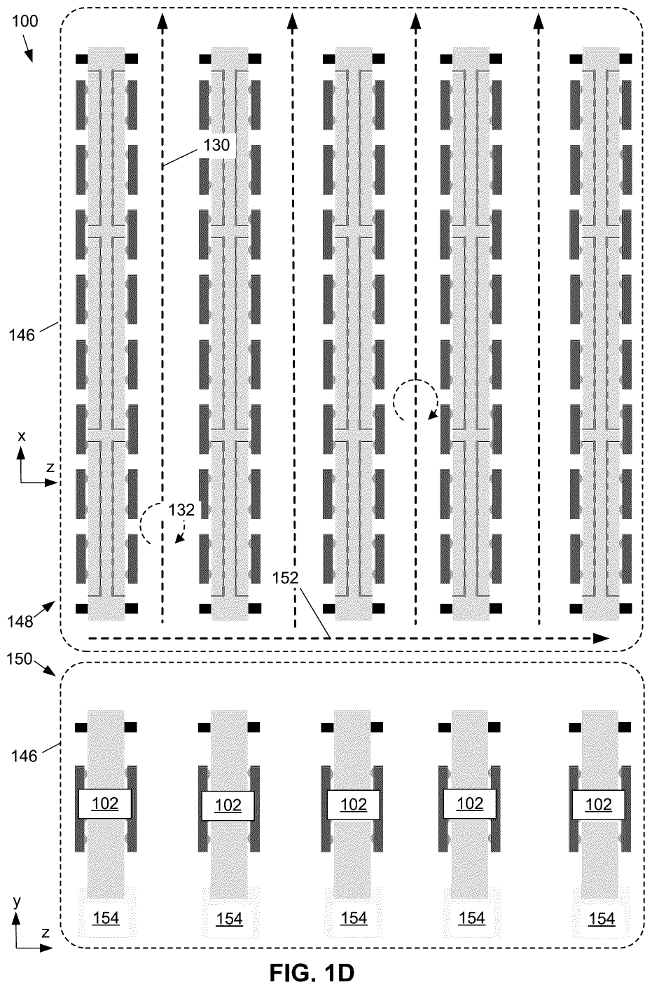

FIGS. 1A-1D are diagrams of an example implementation 100 of a memory module 102 described herein. In some implementations, the memory module 102 is included in a computing device such as a server, a computer, a mobile phone, a wired or wireless communication device, a network device, a device in a data center, a device in a cloud computing environment, a vehicle (e.g., an automobile or an airplane), and/or an Internet of Things (IoT) device.

FIG. 1A includes a front view 104, a side section view 106 (e.g., a section view along section line A-A), and a side end view 108 of the memory module 102. As shown in front view 104 of FIG. 1A, the memory module 102 includes a multi-layer substrate 110 (e.g., an interposer). The multi-layer substrate 110 may include a combination of dielectric layers and conductive layers that are interspersed with one another in a vertically-arranged stack. For example, and in some implementations, the multi-layer substrate 110 corresponds to a printed circuit board (PCB) type of substrate that includes dielectric layers having fiberglass-reinforced epoxy resin material interspersed with conductive layers having a metal material such as a copper material or an aluminum material, among other examples. As another example, and in some implementations, the multi-layer substrate 110 corresponds to an interposer type of substrate that includes dielectric layers having a ceramic material interspersed with conductive layers having a metal material such as a silver material or a gold material, among other examples. However, other types of substrates and/or combinations of materials for the dielectric layers and/or the conductive layers are within the scope of the present disclosure.

As further shown in front view 104 of FIG. 1A, the memory module 102 is populated with semiconductor die packages 112. Each of the semiconductor die packages 112 may be a ball grid array (BGA) type of semiconductor die package or a thin small outline package (TSOP) type of semiconductor die package, among other examples. In some implementations, each of the semiconductor die packages 112 includes a casing (e.g., an epoxy mold compound) that encapsulates at least one integrated circuit die. The integrated circuit die may include a memory device such as a DRAM device, a NAND device, or a NOR device, among other examples. Additionally, or alternatively, the integrated circuit die may include a power management device, an inductor device, or a voltage regulator device. The semiconductor die packages 112 may be mounted and/or connected to pads of the memory module 102.

The memory module 102 further includes a linear array of edge connector pads 114. The linear array of edge connector pads 114, which may include a conductive material such as a copper material or an aluminum material, may communicatively couple the memory module 102 to a computing device that hosts the memory module 102.

As further shown in front view 104 of FIG. 1A, the memory module 102 includes at least one cavity region 116 proximate to an edge of the memory module 102. The cavity region 116 includes a linear array of planar fins 118 that extends into the cavity region 116 along the edge of the multi-layer substrate 110. As described in greater detail in connection with FIGS. 1B-1D and elsewhere herein, the linear array of planar fins 118 may be part of a thermal control network that controls junction temperatures of integrated circuit dies included in the semiconductor die packages 112.

In some implementations, the memory module 102 includes extension regions 120 that are proximate to sides of the cavity region 116. The extension regions 120 may be configured to increase a robustness of the multi-layer substrate 110 and/or protect the linear array of planar fins 118.

As further shown in front view 104 of FIG. 1A, the memory module 102 may include a turbulator structure 122 proximate to the cavity region 116. The turbulator structure 122 may be a pin-like structure that protrudes from a surface of the multi-layer substrate 110 and may include a stainless-steel material, among other examples. As described in greater detail with reference to region 124 in connection with FIG. 1B, the turbulator structure 122 may promote a turbulent flow of a fluid flowing over the linear array of planar fins 118 to improve a convective heat transfer performance of the linear array of planar fins 118 and dissipate heat from the memory module 102 to an environment surrounding the memory module 102.

As shown in the side section view 106 of FIG. 1A, and as described in greater detail in connection with FIG. 1C and elsewhere herein, the memory module 102 includes a thermal control network 126. The thermal control network 126 may include one or more fin-based structures 128 that include the linear array of planar fins 118. As shown in the side section view 106, the fin-based structures 128 may be dual-sided fin-based structures that include opposing, planar fins (e.g., planar fins of the linear array of planar fins 118) that extend from two metal layers included in the multi-layer substrate 110. However, in some implementations, the fin-based structures 128 may be single-sided fin-based structures (e.g., fin-based structures that extend from a single metal layer of the multi-layer substrate 110).

As shown in the side end view 108 of FIG. 1A, the turbulator structures 122 extend from the multi-layer substrate 110. In some implementations, the turbulator structures 122 protrude a distance that does not exceed a height of the semiconductor die packages 112.

FIG. 1B shows additional details related to the region 124 of the memory module 102. As shown, the cavity region 116 includes the linear array of planar fins 118. Further, and as shown in FIG. 1B, a fluid 130 flows across the linear array of planar fins 118. In some implementations, the fluid 130 is a gaseous fluid (air or nitrogen, among other examples). In some implementations, the fluid 130 is an inert liquid (an electrically non-conductive, fluorocarbon liquid, among other examples).

As further shown in FIG. 1B, the turbulator structure 122 may disrupt the flow of the fluid 130 and create turbulence pockets 132. The turbulence pockets 132 may increase a Reynold's number of the flow of the fluid 130 and, in accordance with principles of fluid mechanics, increase mixing and a rate of convective heat transfer from the linear array of planar fins 118 to the fluid 130, relative to a flow of the fluid 130 that is primarily a laminar flow. In some implementations, the linear array of planar fins 118 (e.g., the fin-based structures 128) are configured to directly transfer heat to the fluid 130 using thermal convection mechanics.

FIG. 1C shows a magnified end view of the memory module 102 along the section line A-A of FIG. 1A. As shown in FIG. 1C, the memory module 102 includes the semiconductor die package 112a and the semiconductor die package 112b. The semiconductor die package 112a includes at least one integrated circuit die 134a and is connected to the multi-layer substrate 110 using connection structures 136a. In some implementations, a casing (e.g., an epoxy mold compound) encapsulates and/or surrounds the integrated circuit die 134a. The integrated circuit die 134a may include a memory device, a power management device, an inductor device, or a voltage regulator device, among other examples. The connection structures 136a, which are electrically and thermally conductive, may include bump structures, ball structures, or pillar structures, among other examples. Furthermore, the connection structures 136a may include a copper material, a tin-lead alloy material, or a tin-silver-copper alloy material, among other examples.

The semiconductor die package 112b includes at least one integrated circuit die 134b and is connected to an opposite side of the multi-layer substrate 110 using connection structures 136b. The integrated circuit die 134b may include a memory device, a power management device, an inductor device, or a voltage regulator device, among other examples. In some implementations, a casing (e.g., an epoxy mold compound) encapsulates and/or surrounds the integrated circuit die 134b. The connection structures 136b, which are electrically and thermally conductive, may include bump structures, ball structures, or pillar structures, among other examples. Furthermore, the connection structures 136b may include a copper material, a tin-lead alloy material, or a tin-silver-copper alloy material, among other examples.

As shown in FIG. 1C, at least one interconnect 138a (e.g., a trace or a vertical interconnect access structure) connects a conductive layer 140a of the multi-layer substrate 110 with at least one of the connection structures 136a. The interconnect 138a and/or the conductive layer 140a may include a metal material with high thermal conductivity properties, such as a copper material, an aluminum material, a silver material, or a gold material, among other examples.

Additionally, or alternatively, at least one interconnect 138b (e.g., a trace or a vertical interconnect access structure) connects a conductive layer 140b of the multi-layer substrate 110 with at least one of the connection structures 136b. The interconnect 138b and/or the conductive layer 140b may include a metal material with high thermal conductivity properties, such as a copper material, an aluminum material, a silver material, or a gold material, among other examples.

As shown in FIG. 1C, the linear array of planar fins 118a is formed from the conductive layer 140a and the linear array of planar fins 118b is formed from the conductive layer 140b. In some implementations, the conductive layer 140a and/or the conductive layer 140b correspond to a ground plane layer of the memory module 102. In some implementations, the conductive layer 140a and/or the conductive layer 140b correspond to a power plane of the memory module 102. In some implementations, the conductive layer 140a and/or the conductive layer 140b are electrically isolated from the semiconductor die packages 112a and/or 112b. As shown in FIG. 1C, the thermal control network 126 includes the linear arrays of planar fins 118a and 118b, the connection structures 136a and 136b, the interconnects 138a and 138b, and the conductive layers 140a and 140b.

As part of the thermal control network 126, the linear array of planar fins 118a is configured to receive heat 142a (e.g., heat in Joules, calories, or British Thermal Units (BTUs), among other examples) that is generated by integrated circuit devices included as part of the integrated circuit die 134a. The heat 142a may be transferred through the connection structure 136a, the interconnect 138a, and the conductive layer 140a to the linear array of planar fins 118a using thermal conduction heat transfer mechanics. The linear array of planar fins 118a may then dissipate the heat 142a to an environment surrounding the memory module 102 using thermal convection heat transfer mechanics.

Additionally, or alternatively and as part of the thermal control network 126, the linear array of planar fins 118b is configured to receive heat 142b that is generated by integrated circuit devices that may be included as part of the integrated circuit die 134b. The heat 142b may be transferred through the connection structure 136b, the interconnect 138b, and the conductive layer 140b to the linear array of planar fins 118b using thermal conduction heat transfer mechanics. The linear array of planar fins 118b may then dissipate the heat 142b to the environment surrounding the memory module 102 (e.g., the turbulence pockets 132) using thermal convection heat transfer mechanics.

As shown in FIG. 1C, the linear array of planar fins 118a and the linear array of planar fins 118b may combine to form a dual-sided fin-based structure (e.g., a dual-sided fin-based structure that includes opposing, planar fins extending from the two conductive layers 140a and 140b included in the multi-layer substrate 110). As shown in FIG. 1C, a spacer 144 (e.g., a spacer including one or more dielectric or core layers of the multi-layer substrate 110) may separate the linear array of planar fins 118a and the linear array of planar fins 118b (e.g., spacers may be between opposing, planar fins).

Alternatively, and in some implementations, the multi-layer substrate 110 may include a single-sided fin-based structure. In such implementations, the single-sided fin-based structure includes planar fins (e.g., the linear array of planar fins 118a or the linear array of planar fins 118b) extending from a single conductive layer (e.g., the conductive layer 140a or the conductive layer 140b) included in the multi-layer substrate 110.

As described in connection with FIGS. 1A-1C, a semiconductor device assembly (e.g., the memory module 102) includes a multi-layer substrate (e.g., the multi-layer substrate 110) populated with one or more integrated circuit devices (e.g., the semiconductor die packages 112a and/or 112b including the integrated circuit dies 134a and 134b). The multi-layer substrate includes one or more core layers interspersed with one or more vertically-arranged conductive layers (e.g., the conductive layers 140a and/or 140b), where a conductive layer of the vertically-arranged conductive layers includes a linear array of planar fins (e.g., the linear array of planar fins 118a and/or 118b) that extends into a cavity region (e.g., the cavity region 116) along an edge of the multi-layer substrate, and where the linear array of planar fins is configured to receive, through the conductive layer, heat (e.g. the heat 142a and/or 142b) that is generated by the one or more integrated circuit devices, and transfer the heat for dissipation to an environment surrounding the multi-layer substrate populated with the one or more integrated circuit devices.

FIG. 1D shows views of an integrated assembly 146 including a plurality of memory modules 102. The integrated assembly 146 (e.g., a system) may be a computing device such as a server, a computer, a mobile phone, a wired or wireless communication device, a network device, a device in a data center, a device in a cloud computing environment, a vehicle (e.g., an automobile or an airplane), and/or an Internet of Things (IoT) device. FIG. 1D includes a top view 148 and an end view 150.

As shown in the top view 148 of FIG. 1D, the integrated assembly 146 includes an environment providing a flow of the fluid 130. Within the environment, the memory modules 102 are arranged parallel to one another.

As described in connection with FIGS. 1A-1D, an integrated assembly (e.g., the integrated assembly 146) includes an environment providing a flow of a fluid (e.g., the fluid 130) and a plurality of memory module assemblies (e.g., the memory modules 102) arranged parallel to one another within the environment. Each memory module includes a printed circuit board (e.g., the multi-layer substrate 110) and a plurality of memory devices (e.g., the semiconductor die packages 112a and 112b, including the integrated circuit dies 134a and 134b having memory devices) connected to the printed circuit board. A thermal control network (e.g., the thermal control network 126) may be thermally coupled to each of the plurality of memory devices. The thermal control network may include a plurality of fin-based structures (e.g., the fin-based structures 128 that include the linear array of planar fins 118a and/or the linear array of planar fins 118b) extending from the printed circuit board into cavity regions (e.g., the cavity regions 116) of the printed circuit board that are located along an edge of the printed circuit board, where the plurality of fin-based structures are configured to receive heat (e.g., the heat 142a and/or the heat 142b) generated by the memory devices through at least one metal layer (e.g., the conductive layer 140a and/or the conductive layer 140b) included in the printed circuit board, and where the plurality of fin-based structures are configured to transfer the heat to satisfy a junction temperature threshold of the plurality of memory devices.

In some implementations, and as shown in the top view 148, the integrated assembly 146 may include a fluid 152 that flows in a direction that is approximately orthogonal to a flow direction of the fluid 130. The fluid 130 and the fluid 152 may be a same type of fluid.

As shown in the end view 150 of FIG. 1D, a connector 154 is joined with each of the memory modules 102. As an example, the connector 154 may be an elongated socket with flexible, conductive pins that connect with pads (e.g., the edge connector pads 114) of the memory module 102. The connector 154 may route signals between the memory module 102 and other devices that may be included in the integrated assembly 146 (e.g., processors or other computing devices).

As indicated above, FIGS. 1A-1D are provided as an example. Other examples may differ from what is described with regard to FIGS. 1A-1D.

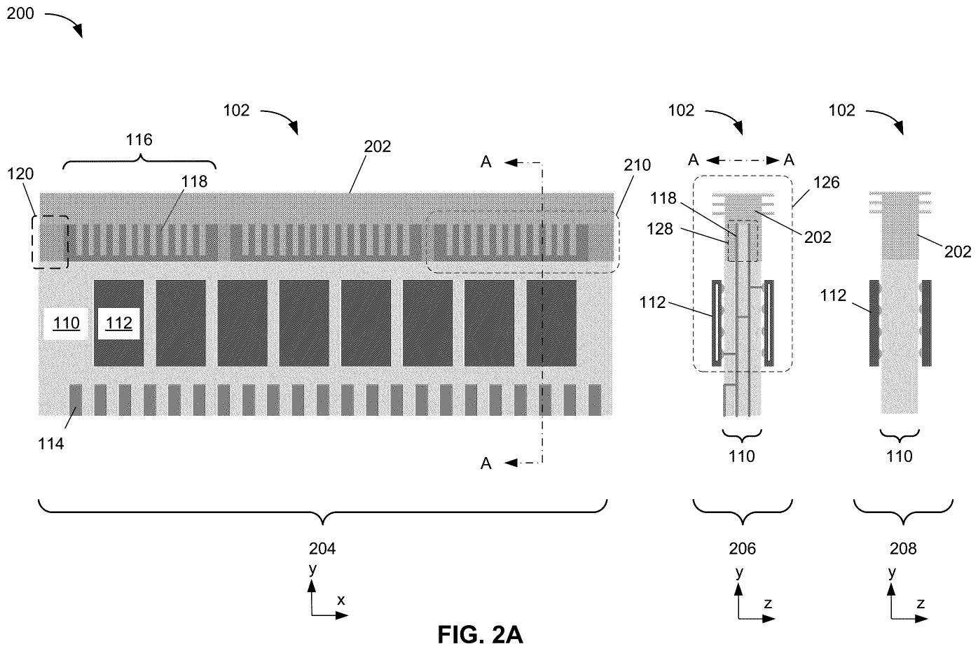

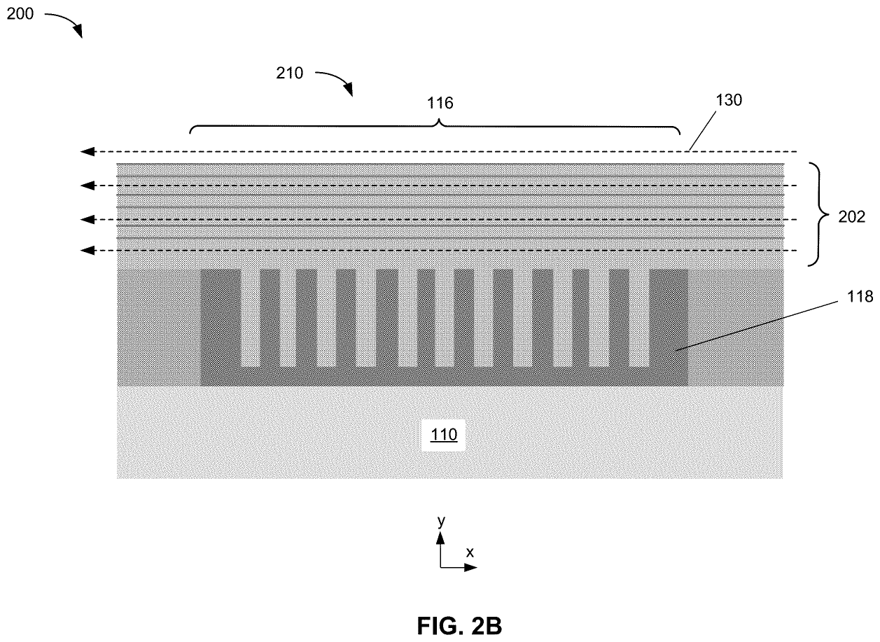

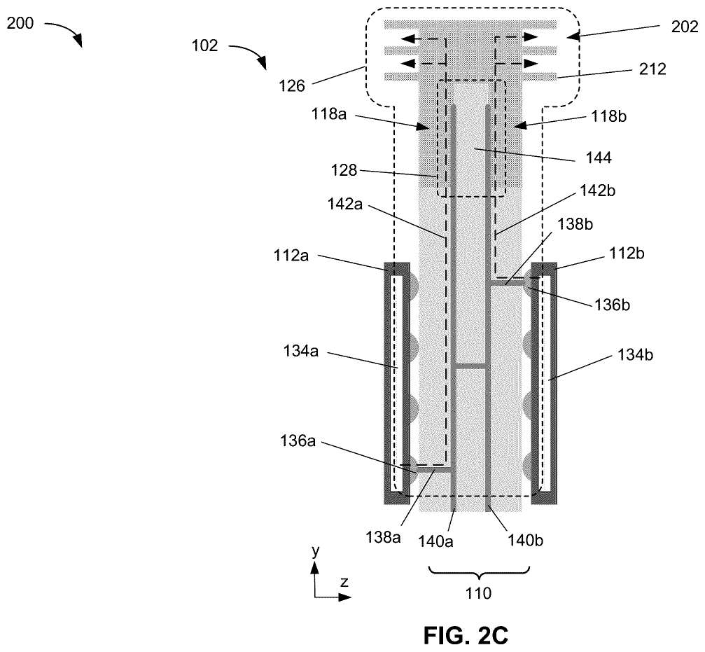

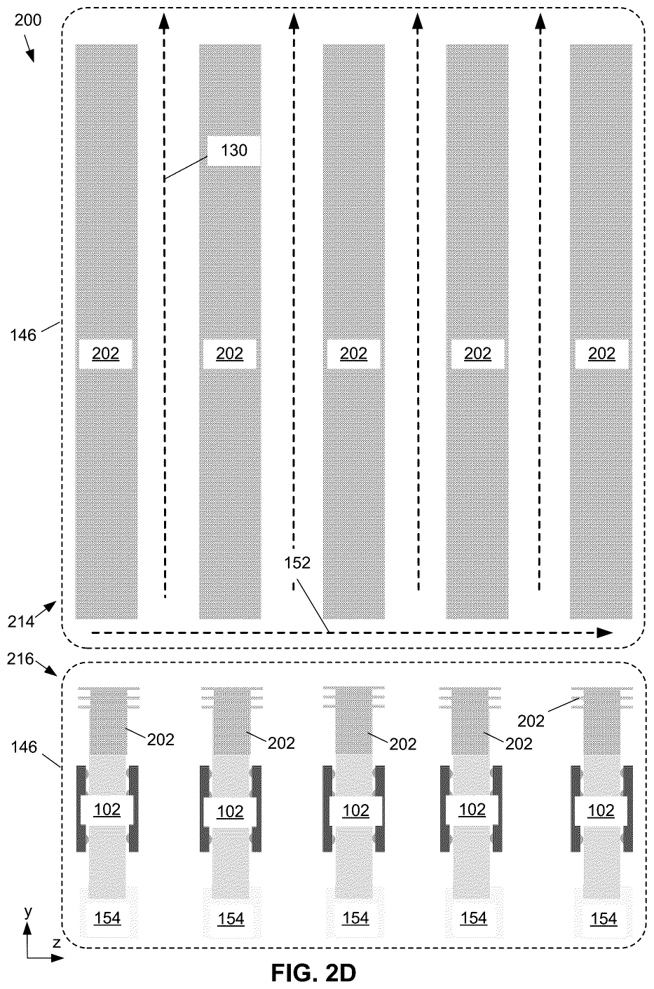

FIGS. 2A-2D are diagrams of an example implementation 200 of the memory module 102 described herein. In contrast to the implementation 100 of FIGS. 1A-1D, the memory module 102 of implementation 200 includes a heat transfer structure 202. Further, the memory module 102 of implementation 200 does not include a turbulator structure (e.g., does not include the turbulator structure 122).

FIG. 2A includes a front view 204, a side section view 206 (e.g., a section view along the section line A-A), and a side end view 208 of the memory module 102. The front view 204 of FIG. 2A shows region 210. In addition to features described in connection with FIG. 1A, the memory module 102 includes the heat transfer structure 202 that is on and/or over the linear array of planar fins 118. As described in greater detail in connection with FIG. 2B with reference to region 210, the heat transfer structure 202 may be a heat sink with fins and/or channels that increase a surface area to transfer heat to the environment surrounding the memory module 102 using thermal convection heat transfer mechanics. The heat transfer structure 202 may include a metal material with high thermal conductivity such as a copper material or an aluminum material, among other examples.

As shown in the side section view 206, and as described in greater detail in connection with FIG. 2C, the memory module 102 includes the thermal control network 126. The thermal control network 126 may include the heat transfer structure 202.

The side end view 208 of FIG. 2A shows the heat transfer structure 202 extending from an edge of the multi-layer substrate 110. Further, the side end view 208 of FIG. 2A does not include the turbulator structures 122 of FIGS. 1A-1D.

FIG. 2B shows additional details related to the region 210 of the memory module 102. In addition to features described in connection with FIG. 1B, and as shown in FIG. 2B, the memory module 102 includes the heat transfer structure 202. As shown in FIG. 2B, the heat transfer structure 202 is on and/or over the linear array of planar fins 118. In other words, the heat transfer structure 202 and the linear array of planar fins 118 are thermally coupled.

As shown in FIG. 2B, the fluid 130 flows through channels and/or fin structures included in the heat transfer structure 202. In FIG. 2B, the fluid 130 may have a flow that is more laminar relative to the flow of the fluid 130 as described in connection with FIG. 1B. However, and due to an increase in available surface area using the channels and/or fin structures of the heat transfer structure 202, heat may be efficiently dissipated to the fluid 130.

In some implementations, the fluid 130 is a gaseous fluid (air or nitrogen, among other examples). In some implementations, the fluid 130 is an inert liquid fluid (an electrically non-conductive, fluorocarbon liquid fluid among other examples).

FIG. 2C shows a magnified end view of the memory module 102 along the section line A-A of FIG. 2B. In addition to features as described in connection with FIG. 1C, and as shown in FIG. 2C, the thermal control network 126 includes the heat transfer structure 202. The heat transfer structure 202 may include one or more fins 212 that extent laterally from the heat transfer structure 202 to an environment surrounding the memory module 102. As shown in FIG. 2C, the one or more fins 212 may be separated by channels or grooves within the heat transfer structure 202.

As part of the thermal control network 126, the heat transfer structure 202 is configured to receive heat 142a that is generated by integrated circuit devices included as part of the integrated circuit die 134a. The heat 142a may be transferred through the connection structure 136a, the interconnect 138a, the conductive layer 140a, the linear array of planar fins 118a, and to the heat transfer structure 202 using thermal conduction heat transfer mechanics. The heat transfer structure 202, configured to receive the heat 142a from the linear array of planar fins 118a using thermal conduction heat transfer mechanics, may then dissipate the heat 142a to an environment that surrounds the memory module 102 using thermal convection heat transfer mechanics.

Additionally, or alternatively and as part of the thermal control network 126, the heat transfer structure 202 is configured to receive heat 142b that is generated by integrated circuit devices that may be included as part of the integrated circuit die 134b. The heat 142b may be transferred through the connection structure 136b, the interconnect 138b, the conductive layer 140b, the linear array of planar fins 118b, and to the heat transfer structure 202 using thermal conduction heat transfer mechanics. The heat transfer structure 202, configured to receive the heat 142b from the linear array of planar fins 118b using thermal conduction heat transfer mechanics, may then dissipate the heat 142b to the environment surrounding the memory module 102 using thermal convection heat transfer mechanics.

FIG. 2D shows views of an integrated assembly 146 including a plurality of memory modules 102. The integrated assembly 146 (e.g., a system) may be a computing device such as a server, a computer, a mobile phone, a wired or wireless communication device, a network device, a device in a data center, a device in a cloud computing environment, a vehicle (e.g., an automobile or an airplane), and/or an IoT device. FIG. 2D includes a top view 214 and an end view 216.

As indicated above, FIGS. 2A-2D are provided as an example. Other examples may differ from what is described with regard to FIGS. 2A-2D.

FIGS. 1A-1D and 2A-2D describe implementations of a memory module (e.g., the memory module 102) that includes a thermal control network (e.g., the thermal control network 126) that uses a conductive layer (e.g., the conductive layer 140a and/or the conductive layer 140b) included in a substrate (e.g., the multi-layer substrate 110) of the memory module. The conductive layer, which may correspond to a ground plane layer, may be formed from a metal material having a high thermal conductivity. As part of the thermal control network, a linear array of planar fins (e.g., the linear array of planar fins 118) that are part of the conductive layer extend into cavity regions proximate to an edge of the substrate.

In some implementations, the conductive layer is connected to DRAM devices (e.g., the integrated circuit dies 134a and/or 134b) of the memory module using interconnects (e.g. the interconnects 138a and/or 138b) that are routed through layers of the substrate and/or connection structures (e.g., the connection structures 136a and/or 136b) that connect semiconductor die packages (e.g., the semiconductor die packages 112a and/or 112b) including the DRAM device with the substrate. By transferring heat (e.g., the heat 142a and/or 142b) through the connection structures, through the interconnects, and through the conductive layer to the linear array of planar fins, the thermal control network of the memory module will have an improved heat transfer efficiency relative to another thermal control network that transfers heat from the DRAM devices through a casing and a heat spreader above the DRAM devices.

In this way, the thermal control network maintains a junction temperature of the DRAM devices at or below a threshold temperature that adversely affects a refresh performance of the DRAM devices. By maintaining the refresh performance of the DRAM devices, the memory module may realize improved performance benefits that include improved data retention, improved stability, lower power consumption, and/or lower heat generation, among other examples.

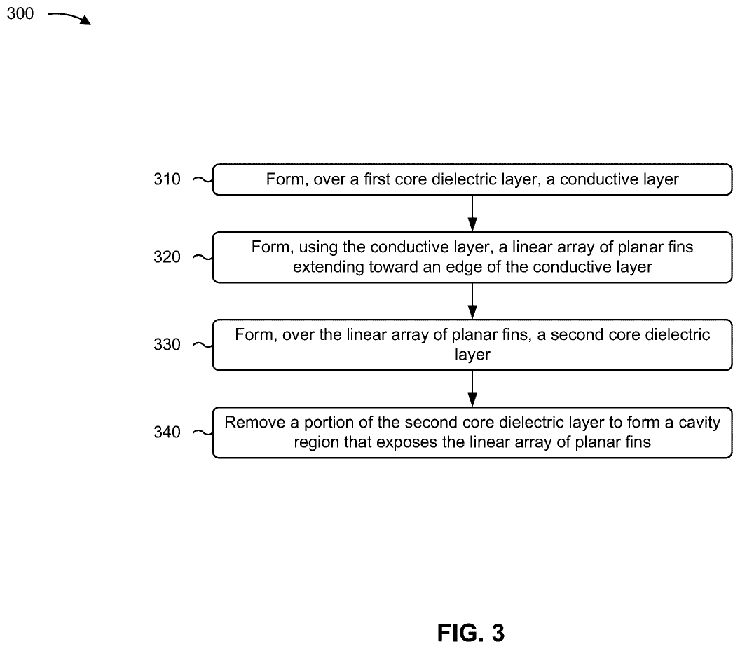

FIG. 3 is a flowchart of an example method 300 associated forming a multi-layer substrate (e.g., the multi-layer substrate 110) described herein. In some implementations, one or more semiconductor processing tools of a multi-layer substrate manufacturing line (a printed circuit board manufacturing line or a ceramic substrate manufacturing line, among other examples) may perform or may be configured to perform one or more operations included in the method 300. In some implementations, another device or a group of devices separate from or including the one or more semiconductor processing tools may perform or may be configured to perform the one or more operations. Additionally, or alternatively, one or more components of the one or more semiconductor processing tools may perform or may be configured to perform the one or more operations. Thus, means for performing the method 300 may include the one or more semiconductor processing tools and/or one or more components of the semiconductor processing tools. Additionally, or alternatively, a non-transitory computer-readable medium may store one or more instructions that, when executed by the one or more semiconductor processing tools, cause the one or more semiconductor processing tools to perform the one or more operations.

As shown in FIG. 3, the method 300 may include forming, over a first core dielectric layer, a conductive layer (e.g., the conductive layer 140a) (block 310). As further shown in FIG. 3, the method 300 may include forming, using the conductive layer, a linear array of planar fins (e.g., the linear array of planar fins 118a) extending toward an edge of the conductive layer (block 320). As further shown in FIG. 3, the method 300 may include forming, over the linear array of planar fins, a second core dielectric layer (block 330). As further shown in FIG. 3, the method 300 may include removing a portion of the second core dielectric layer to form a cavity region (e.g., the cavity region 116) that exposes the linear array of planar fins (block 340).

The method 300 may include additional aspects, such as any single aspect or any combination of aspects described below and/or described in connection with one or more other methods or operations described elsewhere herein.

In a first aspect, forming the conductive layer includes depositing the conductive layer using a deposition process.

In a second aspect, alone or in combination with the first aspect, forming the linear array of planar fins extending toward the edge of the conductive layer includes patterning the linear array of planar fins using a lithography process.

In a third aspect, alone or in combination with one or more of the first and second aspects, the method 300 includes forming a heat transfer structure on the linear array of planar fins.

In a fourth aspect, alone or in combination with one or more of the first through third aspects, the method 300 includes forming a turbulator structure over the second core dielectric layer and proximate to the cavity region.

The method 300 may include additional aspects, such as any single aspect or any combination of aspects described below and/or described in connection with one or more other methods or operations described elsewhere herein.

Although FIG. 3 shows example blocks of a method 300, in some implementations, the method 300 may include additional blocks, fewer blocks, different blocks, or differently arranged blocks than those depicted in FIG. 3. Additionally, or alternatively, two or more of the blocks of the method 300 may be performed in parallel. The method 300 is an example of one method that may be performed by one or more devices described herein. These one or more devices may perform or may be configured to perform one or more other methods based on operations described herein.

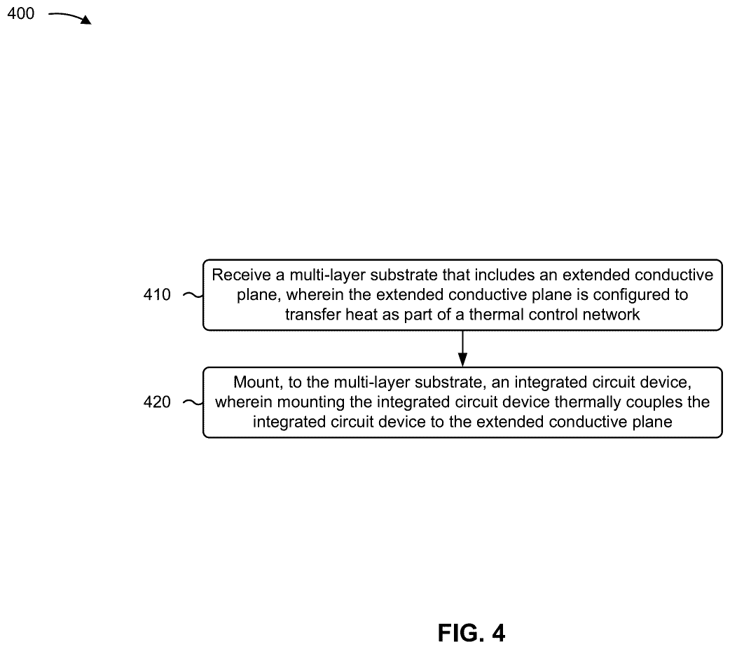

FIG. 4 is a flowchart of an example method 400 associated with forming a memory module (e.g., the memory module 102) described herein. In some implementations, one or more semiconductor processing tools of a board assembly or a surface mount (SMT) manufacturing line may perform or may be configured to perform one or more operations included in the method 400. In some implementations, another device or a group of devices separate from or including the one or more semiconductor processing tools may perform or may be configured to perform the one or more operations. Additionally, or alternatively, one or more components of the one or more semiconductor processing tools may perform or may be configured to perform the one or more operations. Thus, means for performing the method 400 may include the one or more semiconductor processing tools and/or one or more components of the semiconductor processing tools. Additionally, or alternatively, a non-transitory computer-readable medium may store one or more instructions that, when executed by the one or more semiconductor processing tools, cause the one or more semiconductor processing tools to perform the one or more operations.

As shown in FIG. 4, the method 400 may include receiving a multi-layer substrate (e.g., the multi-layer substrate 110) that includes an extended conductive plane (e.g., the conductive layer 140a including the linear array of planar fins 118a and/or the conductive layer 140b including the linear array of planar fins 118b), where the extended conductive plane is configured to transfer heat (e.g., the heat 142a and/or the heat 142b) as part of a thermal control network (e.g., the thermal control network 126) (block 410). As further shown in FIG. 4, the method 400 may include mounting, to the multi-layer substrate, an integrated circuit device (e.g., the semiconductor die package 112a including the integrated circuit die 134a and/or the semiconductor die package 112b including the integrated circuit die 134b), where mounting the integrated circuit device thermally couples the integrated circuit device to the extended conductive plane (block 420).

The method 400 may include additional aspects, such as any single aspect or any combination of aspects described below and/or described in connection with one or more other methods or operations described elsewhere herein.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

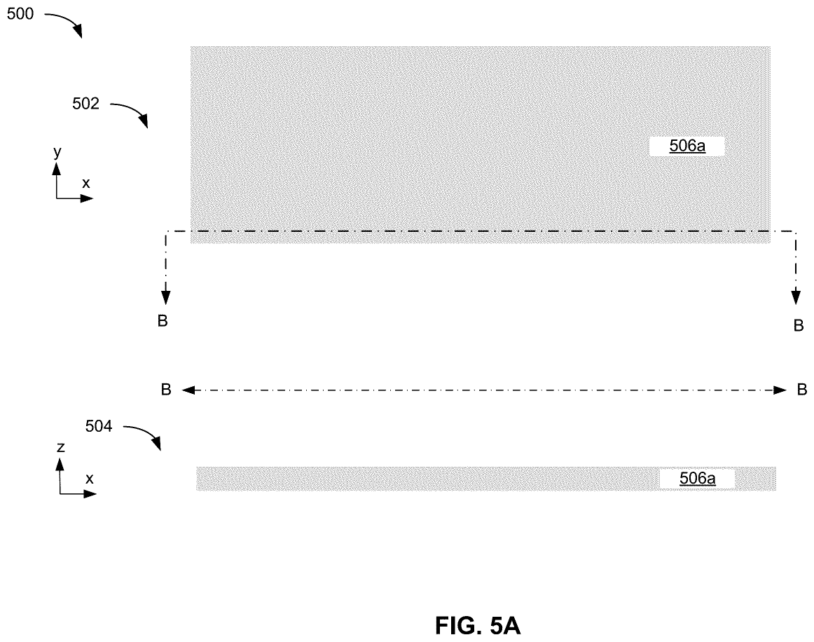

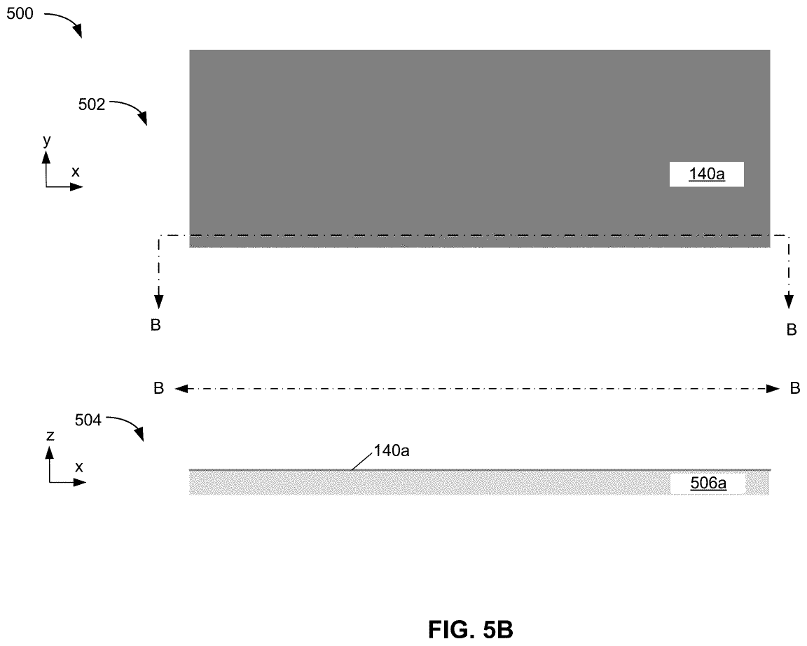

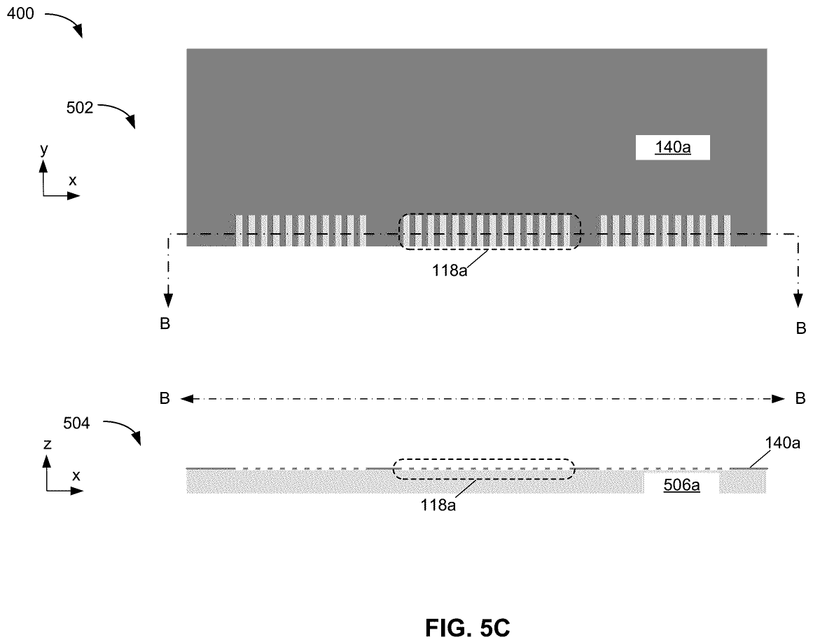

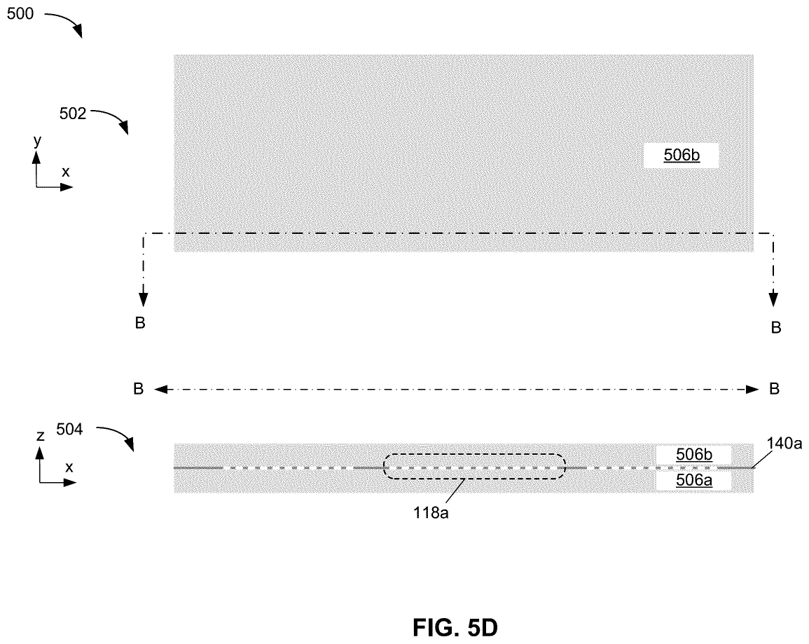

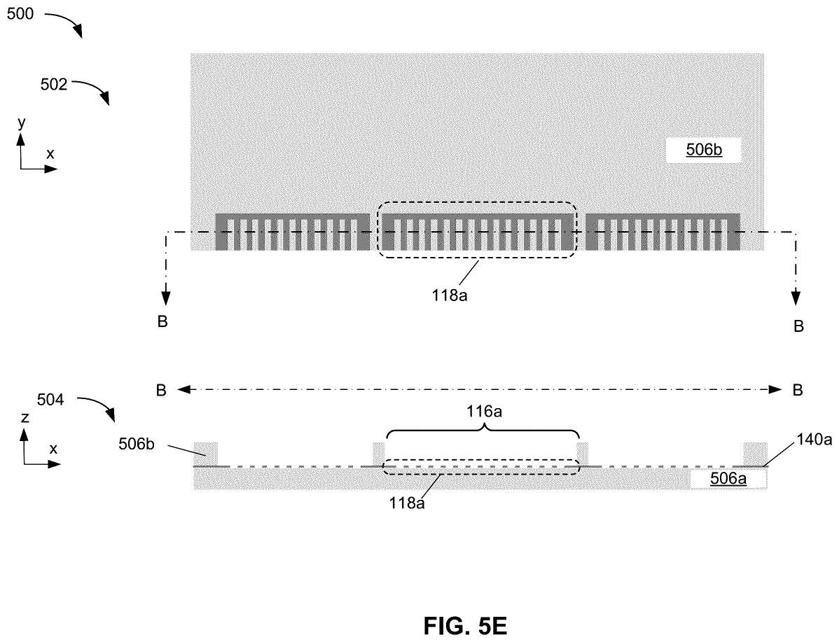

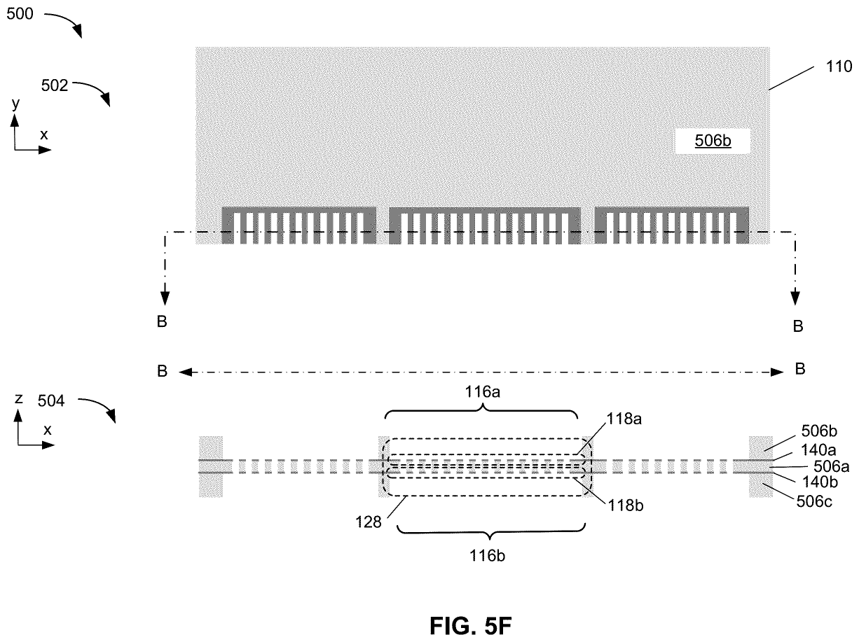

FIGS. 5A-5F describe an example series of manufacturing operations 500 that may be performed to form a multi-layer substrate with an extended conductive plane. Each of the figures includes a top view 502 and a side section view 504, where the side section view 504 is along the section line B-B.

In some implementations, the multi-layer substrate of FIGS. 5A-5F corresponds to the multi-layer substrate 110 having the linear array of planar fins 118 as described in connection with FIGS. 1A-1D, 2A-2D, and elsewhere herein. Furthermore, one or more of the series of manufacturing operations 500 may correspond to one or more of the blocks described in connection with the method 300 of FIG. 3 and/or the method 400 of FIG. 4.

FIG. 5A shows a dielectric layer 506a (e.g., a first dielectric layer). As an example, and in some implementations, the dielectric layer 506a (e.g., a core layer) includes a fiberglass-reinforced epoxy resin material that includes an epoxy resin, layers of woven fiberglass cloth, and additives or fillers to enhance a property of the dielectric layer 506a (e.g., a flame resistance or a thermal conductivity of the dielectric layer 506a). In such cases, formation of the dielectric layer 506a may include using a lamination tool to form the dielectric layer 506a. As another example, and in some implementations, the dielectric layer 506a includes a ceramic material such as an aluminum dioxide material or an aluminum nitride material. In such cases, formation of the dielectric layer 506a may include using a screen-printing tool and/or a sintering tool to form the dielectric layer 506a.

FIG. 5B shows formation of the conductive layer 140a on or over the dielectric layer 506a. As an example, formation of the conductive layer 140a over the dielectric layer 506a may include using a lamination tool to perform a lamination operation (e.g., a cladding operation) that forms a layer of a conductive material (e.g., a copper material or an aluminum material) over the dielectric layer 506a. As another example, formation of the conductive layer 140a over the dielectric layer 506a may include using a deposition tool to perform a deposition operation (e.g., a physical vapor deposition operation or a chemical vapor deposition operation) that forms the layer of the conductive material over the dielectric layer. As another example, formation of the conductive layer 140a over the dielectric layer 506a may include using a plating tool to perform a plating operation (e.g., an electroplating operation) that forms the layer of the conductive material over the dielectric layer 506a.

FIG. 5C shows formation of the linear array of planar fins 118a from the conductive layer 140a. As an example, formation of the linear array of planar fins 118a may include using an exposure tool and an etch tool to perform one or more patterning operations (e.g., a lithography operation and an etch operation) that form the linear array of planar fins 118a from the conductive layer 140a.

FIG. 5D shows formation of the dielectric layer 506b (e.g., a second dielectric layer) over the conductive layer 140a and/or the linear array of planar fins 118a. As an example, and in some implementations, the dielectric layer 506b (e.g., a core layer) includes a fiberglass-reinforced epoxy resin material that includes an epoxy resin, layers of woven fiberglass cloth, and additives or fillers to enhance a property of the dielectric layer 506b (e.g., a flame resistance or a thermal conductivity of the dielectric layer 506b). In such cases, formation of the dielectric layer 506b may include using a lamination tool to form the dielectric layer 506b. As another example, and in some implementations, the dielectric layer 506b includes a ceramic material such as an aluminum dioxide material or an aluminum nitride material. In such cases, formation of the dielectric layer 506b may include using a screen-printing tool and/or a sintering tool to form the dielectric layer 506b.

FIG. 5E shows formation of the cavity region 116a (e.g., a first portion of the cavity region 116) in the dielectric layer 506b to expose the linear array of planar fins 118a. Formation of the cavity region 116a may include using an exposure tool and an etch tool to perform one or more patterning operations (e.g., a lithography operation and an etch operation) that remove material from the dielectric layer 506b to form the cavity region 116a.

FIG. 5F shows formation of additional portions of the multi-layer substrate 110. Using techniques similar to those described in FIGS. 5A-5E, formation of the additional portions of the multi-layer substrate 110 may include formation of the conductive layer 140b, the planar fins 118b, the dielectric layer 506c (e.g., a third dielectric layer), and the cavity region 116b (e.g., a second portion of the cavity region 116). As shown in FIG. 5F, the multi-layer substrate 110 includes one or more core layers (e.g., the dielectric layers 506a, 506b, and 506c) that are interspersed with one or more vertically-arranged conductive layers (e.g., the conductive layers 140a and 140b).

As indicated above, FIGS. 5A-5F are provided as an example. Other examples may differ from what is described with regard to FIGS. 5A-5F.

In some implementations, a semiconductor device assembly includes a multi-layer substrate populated with one or more integrated circuit devices, comprising: one or more core layers interspersed with one or more vertically-arranged conductive layers, wherein a conductive layer of the vertically-arranged conductive layers comprises a linear array of planar fins that extends into a cavity region along an edge of the multi-layer substrate, and wherein the linear array of planar fins is configured to receive, through the conductive layer, heat that is generated by the one or more integrated circuit devices and transfer the heat for dissipation to an environment surrounding the multi-layer substrate populated with the one or more integrated circuit devices.

In some implementations, an integrated assembly includes an environment providing a flow of a fluid; and a plurality of memory module assemblies arranged parallel to one another within the environment, each memory module assembly comprising: a printed circuit board; and a plurality of memory devices connected to the printed circuit board; and a thermal control network thermally coupled to each of the plurality of memory devices, comprising: a plurality of fin-based structures extending from the printed circuit board into cavity regions of the printed circuit board that are located along an edge of the printed circuit board, wherein the plurality of fin-based structures are configured to receive heat generated by the memory devices through at least one metal layer included in the printed circuit board, and wherein the plurality of fin-based structures are configured to transfer the heat to satisfy a junction temperature threshold of the plurality of memory devices.

In some implementations, a method includes forming, over a first core dielectric layer, a conductive layer; forming, using the conductive layer, a linear array of planar fins extending toward an edge of the conductive layer; forming, over the linear array of planar fins, a second core dielectric layer; and removing a portion of the second core dielectric layer to form a cavity region that exposes the linear array of planar fins.

In some implementations, a method includes receiving a multi-layer substrate that includes an extended conductive plane, where the extended conductive plane is configured to transfer heat as part of a thermal control network; and mounting, to the multi-layer substrate, an integrated circuit device, where mounting the integrated circuit device thermally couples the integrated circuit device to the extended conductive plane.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a multi-layer substrate populated with one or more integrated circuit devices, comprising:
one or more core layers interspersed with one or more vertically-arranged conductive layers,
wherein a conductive layer of the vertically-arranged conductive layers comprises a linear array of planar fins that extends into a cavity region along an edge of the multi-layer substrate, and
wherein the linear array of planar fins is configured to receive, through the conductive layer, heat that is generated by the one or more integrated circuit devices and transfer the heat for dissipation to an environment surrounding the multi-layer substrate populated with the one or more integrated circuit devices.

2. The semiconductor device assembly of claim 1, wherein the one or more core layers comprise:
a fiberglass-reinforced epoxy resin material.

3. The semiconductor device assembly of claim 1, wherein the one or more core layers comprise:
a ceramic material.

4. The semiconductor device assembly of claim 1, wherein the conductive layer comprises:
a copper material,
an aluminum material,
a silver material, or
a gold material.

5. The semiconductor device assembly of claim 1, wherein the conductive layer is a ground plane layer.

6. The semiconductor device assembly of claim 1, wherein the one or more integrated circuit devices comprise:
a memory device,
a power management device,
an inductor device, or
a voltage regulator device.

7. The semiconductor device assembly of claim 1, further comprising:
a turbulator structure that is proximate to the cavity region.

8. The semiconductor device assembly of claim 1, further comprising:
a heat transfer structure along the edge of the multi-layer substrate and thermally coupled with the linear array of planar fins.

9. The semiconductor device assembly of claim 8, wherein the heat transfer structure is configured to receive the heat from the linear array of planar fins using thermal conduction, and
wherein the heat transfer structure is configured to dissipate the heat to the environment using thermal convection.

10. The semiconductor device assembly of claim 8, wherein the heat transfer structure comprises:
fin structures.

11. An integrated assembly, comprising:
an environment providing a flow of a fluid; and
a plurality of memory module assemblies arranged parallel to one another within the environment, each memory module assembly comprising:
a printed circuit board; and
a plurality of memory devices connected to the printed circuit board; and
a thermal control network thermally coupled to each of the plurality of memory devices, comprising:
a plurality of fin-based structures extending from the printed circuit board into cavity regions of the printed circuit board that are located along an edge of the printed circuit board,
wherein the plurality of fin-based structures are configured to receive heat generated by the memory devices through at least one metal layer included in the printed circuit board, and
wherein the plurality of fin-based structures are configured to transfer the heat to satisfy a junction temperature threshold of the plurality of memory devices.

12. The integrated assembly of claim 11, wherein the printed circuit board comprises:
extension regions that are proximate to sides of the cavity regions that are configured to protect the plurality of fin-based structures.

13. The integrated assembly of claim 11, wherein the plurality of fin-based structures comprises:
single-sided fin-based structures including planar fins extending from a single conductive layer included in the printed circuit board.

14. The integrated assembly of claim 11, wherein the plurality of fin-based structures comprises:
dual-sided fin-based structures including opposing, planar fins extending from two conductive layers included in the printed circuit board.

15. The integrated assembly of claim 14, wherein the plurality of fin-based structures further comprise:
spacers between the opposing, planar fins.

16. The integrated assembly of claim 11, wherein the thermal control network further comprises:
connection structures that connect semiconductor die packages including the plurality of memory devices with the printed circuit board, and interconnects that connect the connection structures with metal layers used to form the plurality of fin-based structures.

17. The integrated assembly of claim 11, wherein the fluid is a gaseous fluid.

18. The integrated assembly of claim 11, wherein the fluid is a liquid fluid.

19. The integrated assembly of claim 11, wherein the plurality of fin-based structures are configured to directly transfer the heat, to the fluid, using convection.

20. The integrated assembly of claim 11, wherein the thermal control network further comprises:
a heat transfer structure along the edge of the printed circuit board and thermally coupled with the plurality of fin-based structures.

21. A method, comprising:
forming, over a first core dielectric layer, a conductive layer;
forming, using the conductive layer, a linear array of planar fins extending toward an edge of the conductive layer;
forming, over the linear array of planar fins, a second core dielectric layer; and
removing a portion of the second core dielectric layer to form a cavity region that exposes the linear array of planar fins.

22. The method of claim 21, wherein forming the conductive layer includes:
using a lamination operation to form the conductive layer on the first core dielectric layer, or
using a deposition operation to form the conductive layer on the first core dielectric layer.

23. The method of claim 21, wherein forming the linear array of planar fins extending toward the edge of the conductive layer includes:
using a patterning operation to form the linear array of planar fins.

24. The method of claim 21, further including:
forming a heat transfer structure on the linear array of planar fins.

25. The method of claim 21, further including:
forming a turbulator structure over the second core dielectric layer and proximate to the cavity region.
